(19) United States
(12) Patent Application Publication
(10) Pub. No.: US 2012/0292684 A1
(43) Pub. Date: Nov. 22, 2012

(54) NON-VOLATILE MEMORY DEVICE AND METHOD FOR FABRICATING THE SAME

(76) Inventor: Cha-Deok DONG, Gyeonggi-do (KR)

(21) Appl. No.: 13/330,135

(22) Filed: Dec. 19, 2011

(30) Foreign Application Priority Data
May 20, 2011 (KR) 10-2011-0047964

(51) Int. Cl. H01L 29/788; H01L 21/762

(52) U.S. Cl. 257/316; 438/424; 257/E29.3; 257/E21.546

(57) ABSTRACT

A non-volatile memory device includes a first storage layer making contact with a sidewall of an active region in an isolation trench and a second charge storage layer making contact with an opposite sidewall of the active region in the isolation trench, first and second tunnel insulation layers interposed between the first charge storage layer and the active region and between the second charge storage layer and the active region, a first charge blocking layer disposed over the first and second charge storage layers, and a control gate disposed over the first charge blocking layer.

### CROSS-REFERENCE TO RELATED APPLICATIONS

The present application claims priority of Korean Patent Application No. 10-2011-0047964, filed on May 20, 2011, which is incorporated herein by reference in its entirety.

### BACKGROUND

1. Field

Exemplary embodiments of the present invention relate to a non-volatile memory device and a method for fabricating the same.

2. Description of the Related Art

A non-volatile memory device is a memory device where stored data is retained even when a power supply is cut off. An example of a non-volatile memory device is a flash memory.

Examples of non-volatile memory devices include a floating gate non-volatile memory device and a charge trap non-volatile memory device. The floating gate non-volatile memory device stores charge in a floating gate, which is formed of a conductor such as multi-crystalline silicon. Meanwhile, the charge trap non-volatile memory device stores charge in a charge trap layer, which is formed of a non-conductor such as a silicon nitride layer.

As a degree of integration increases and a design rule decreases for a non-volatile memory device, it becomes more difficult to fabricate non-volatile memory devices. Such fabrication difficulties become more pronounced as a multi-level cell non-volatile memory device is fabricated.

### SUMMARY

An exemplary embodiment of the present invention is directed to a non-volatile memory device and a method for fabricating the same, which may increase the degree of integration, while using the same design rule.

In accordance with an embodiment of the present invention, a non-volatile memory device includes: a first charge storage layer making contact with a sidewall of an active region in an isolation trench and a second charge storage layer making contact with an opposite sidewall of the active region in the isolation trench; first and second tunnel insulation layers interposed between the first charge storage layer and the active region and between the second charge storage layer and the active region; a first charge blocking layer disposed over the first and second charge storage layers; and a control gate disposed over the first charge blocking layer.

In accordance with another embodiment of the present invention, a method for fabricating a non-volatile memory device includes: etching a part of a substrate to form an isolation trench that defines an active region; forming a first tunnel insulation layer over a sidewall of the active region in the trench and a second tunnel insulation layer over an opposite sidewall of the active region in the trench; forming first and second charge storage layers on the first and second tunnel insulation layers; forming a first charge blocking layer over the first and second charge storage layers; and forming a control gate conductive layer over the first charge blocking layer.

### BRIEF DESCRIPTION OF THE DRAWINGS

FIGS. 1 to 13 are cross-sectional views illustrating a non-volatile memory device and a method for fabricating the same in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

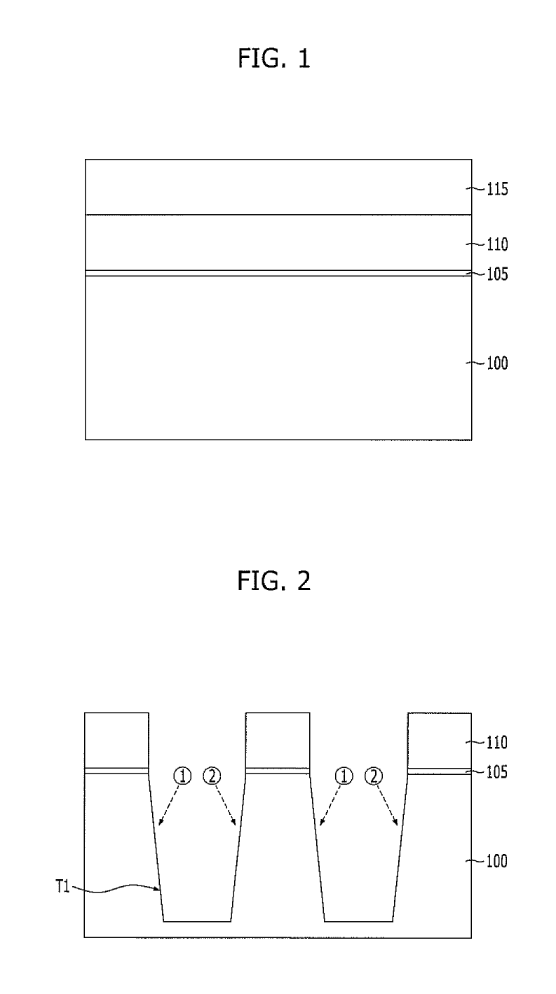

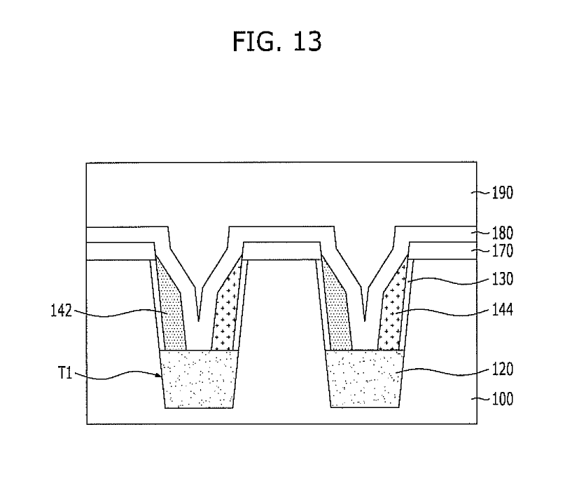

FIGS. 1 to 13 are cross-sectional views illustrating a non-volatile memory device and a method for fabricating the same in accordance with an embodiment of the present invention. Specifically, FIG. 13 is a cross-sectional view illustrating the non-volatile memory device in accordance with an embodiment of the present invention, and FIGS. 1 to 12 are diagrams illustrating intermediate processes for fabricating the device illustrated in FIG. 13.

Referring to FIG. 1, a screen oxide layer 105 is formed on a semiconductor substrate 100. Ion implantation processes of forming wells are performed, and various threshold voltages Vt are adjusted. Then, a pad nitride layer 110 and a hard mask oxide layer 115 are formed on the screen oxide layer 105. The pad nitride layer 110 and the hard mask oxide layer 115 are used in subsequent processes to form isolation trenches.

Referring to FIG. 2, the hard mask oxide layer 115 is selectively etched. The pad nitride layer 110, the screen oxide layer 105, and the semiconductor substrate 100 are subsequently etched using the etched hard mask oxide layer 115 as an etch mask to form isolation trenches T1 in the semiconductor substrate 100.

Through the process of forming the isolation trenches T1, active regions of the substrate 100 are defined, where the active region has two sidewalls exposed by the isolation trench T1. Meanwhile, in the process of forming the isolation trenches T1, the hard mask oxide layer 115 may be removed, or the hard mask oxide layer 115 may be removed through an additional removal process.

Impurity ions used, for example, for controlling a cell threshold voltage, are implanted into both sidewalls of the active region of the isolation trench T1. The impurity ions are implanted with a concentration or energy for one sidewall (for example, a left sidewall, referring to arrow \textcircled{1} of the active region different than the impurity ion concentration or energy for the other sidewall (for example, a right sidewall, referring to arrow \textcircled{2} of the active region. The impurity ion implantation process may be performed by using, for example, a tilt ion implantation process.

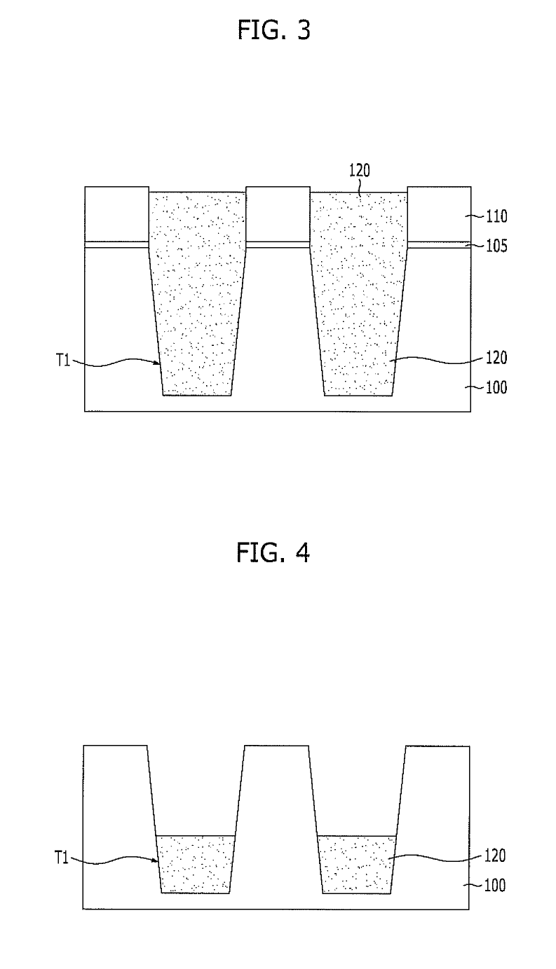

Referring to FIG. 3, an insulation layer (for example, an oxide layer) covering a resultant structure obtained through the process of FIG. 2 is formed such that the isolation trenches T1 are sufficiently filled. A planarization process (for example, a chemical mechanical polishing (CMP) process) is performed on the insulation layer such that the pad nitride layer 110 is exposed. Through the process of FIG. 3, isolation layers 120 are formed in the trenches T1.

Referring to FIG. 4, the exposed pad nitride layer 110 is removed, and a part of the isolation layer 120 is removed such that some of the isolation layer 120 remains in the trench T1 with a desired thickness.

The pad nitride layer 110 may be removed, for example, through a stripping process using, for example, a phosphoric acid solution. Furthermore, a part of the isolation layer 120 may be removed by etching back the isolation layer 120. During the etching of the isolation layer 120, the screen oxide layer 105 may also be removed.

As a result of the process of FIG. 4, part of the substrate 100 protrudes above the isolation layer 120, and both sidewalls of the active region are exposed over the isolation layer 120.

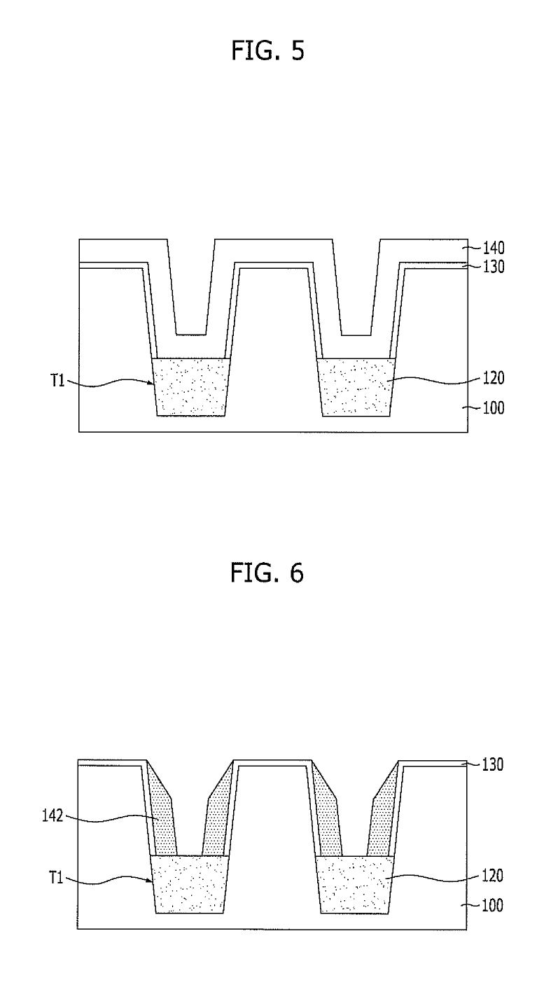

Referring to FIG. 5, a tunnel insulation layer 130 is formed on both sidewalls of the active region exposed over the isolation layer 120 and the upper surface of the substrate 100. However, the present invention is not limited thereto. For example, the tunnel insulation layer 130 may be formed on both sidewalls of the active region. The tunnel insulation layer 130 may be formed using a dry oxidation process, a wet oxidation process, or a radical oxidation process.

When the impurity ion concentration or the ion implantation energy at the one sidewall of the active region is different from the impurity ion concentration or the ion implantation energy at the other sidewall of the active region, the tunnel insulation layer 130 of one sidewall of the active region may have different thicknesses than the other sidewall of the active region. The different thicknesses of the tunnel insulation layer 130 may mean that a memory cell formed on one sidewall of the active region operates differently than a memory cell formed on the other sidewall of the active region.

A charge storage layer 140 is formed on a resultant structure including the tunnel insulation layer 130. The charge storage layer 140 may be formed by depositing a floating gate conductive layer, for example, a polysilicon layer. Also, the charge storage layer 140 may be formed by depositing a charge trap insulation layer, for example, a nitride layer. The charge storage layer 140 may have a thickness which is insufficient for completely filling spaces in the trenches T1.

Referring to FIG. 6, a blanket etching process is performed with respect to the charge storage layer 140. As a result of the blanket etch, charge storage layers 142 are formed. The charge storage layers 142 are separated from each other and make contact with both sidewalls of each active region over the isolation layer 120.

Since the sidewalls of the active region are used, the area of the active region is increased. Furthermore, since the charge storage layers 142 are formed on both sidewalls of the active region, two memory cells are formed in one active region, resulting in an increase in the degree of integration.

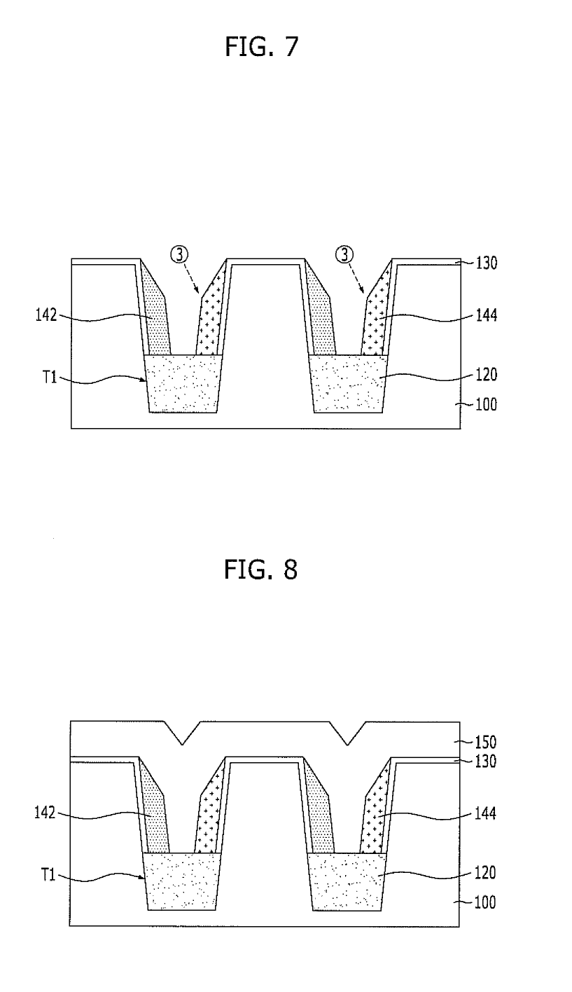

Referring to FIG. 7, impurity ions are implanted into the charge storage layer 142 formed on one sidewall, for example, the right sidewall, of the active region (refer to arrow \textcircled{3}). The charge storage layer 142 that does not have impurity ions implanted will herein be called the first charge storage layer 142. The charge storage layer 142 into which the impurity ions are implanted herein will be called the second charge storage layer and is indicated by reference numeral 144. While FIG. 7 shows the impurity ions being implanted into the right sidewall, the impurity ions may be implanted into the charge storage layer 142 on either sidewall of the active region.

The impurities implanted in the ion implantation process, for example, may include boron (B), phosphorus (P), arsenic (Ar) and the like. Furthermore, the ion implantation process may be performed using a source of N₂, Ar, O₂, N₂O, N₂ and the like.

As a result, the second charge storage layer 144 and the first charge storage layer 142 have different characteristics when the device of the exemplary embodiment operates because impurities are implanted into the second charge storage layer 144 and impurities are not implanted into the first charge storage layer 142. Consequently, two memory cells are formed that independently operate with different characteristics in one active region.

Meanwhile, in an exemplary embodiment, the first and second charge storage layers 142 and 144 with different characteristics are formed because impurity ions are implanted into, for example, only one of the charge storage layers. However, the present invention is not limited thereto. In another embodiment, impurity ions are implanted into both of the charge storage layers. Charge storage layers with different characteristics may still be formed by implanting impurities into the charge storage layer formed on the one sidewall of the active region with a impurity type or concentration that is different from the type or concentration of the impurity ions implanted into the charge storage layer formed on the other sidewall of the active region.

Referring to FIG. 8, a capping layer 150 is formed to cover a resultant structure including the first and second charge storage layers 142 and 144. The capping layer 150 protects the first and second charge storage layers 142 and 144, and may be formed of an insulation layer, for example, a nitride layer.

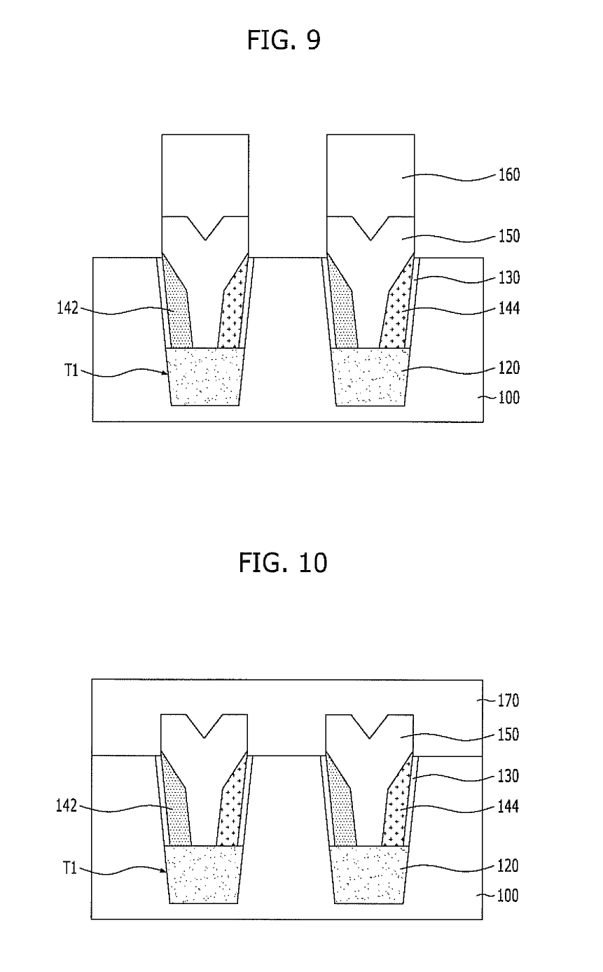

Referring to FIG. 9, a mask pattern 160 is formed on the capping layer 150 to cover the structures formed in the trenches T1. The capping layer 150 not covered by the mask pattern 160 is removed by using a dry etch process or a wet etch process. At this time, the tunnel insulation layer 130 formed on the upper surfaces of the substrate 100 may also be removed.

As a result of the process of FIG. 9, the capping layer 150 fills the trenches T1, in which the first and second charge storage layers 142 and 144 are formed, to protect the first and second charge storage layers 142 and 144, and protrudes above the surface of the substrate 100. The upper surface of the substrate 100 is not covered by the capping layer 150. Meanwhile, the mask pattern 160 may be removed, or the mask pattern 160 may be removed through an additional removal process.

Referring to FIG. 10, the first charge blocking layer 170 is formed to cover the capping layer 150 and the surface of the substrate 100. The first charge blocking layer 170, for example, may be an insulation layer and formed of an oxide layer or a silicon oxynitride (SiON) layer.

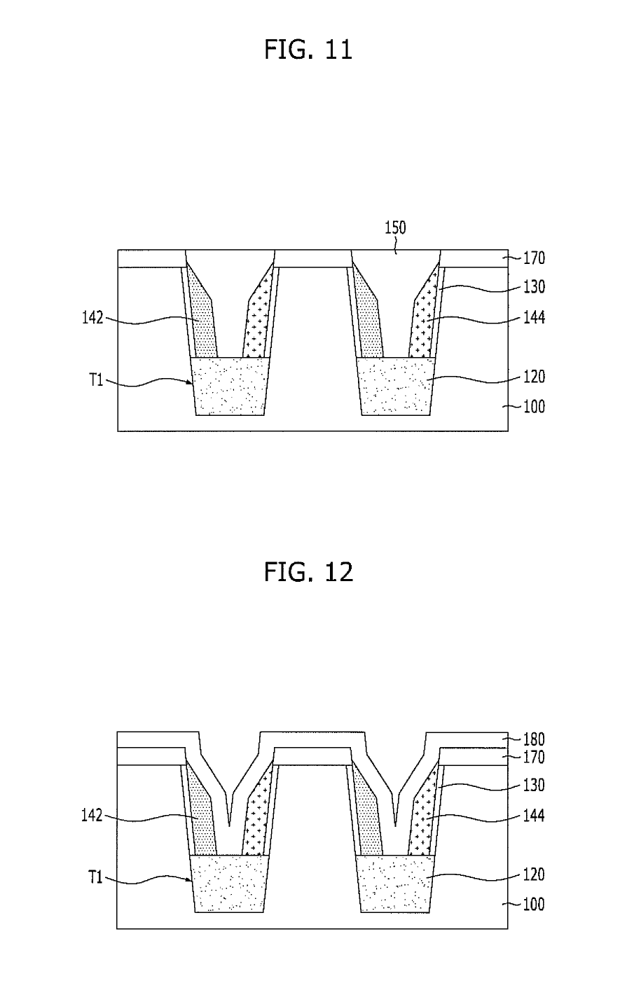

Referring to FIG. 11, a planarization process, for example, a CMP process, is performed until the capping layer 150 is exposed, so that the first charge blocking layer 170 is filled in spaces between the capping layers 150 and also formed on the upper surfaces of the substrate 100.

Referring to FIG. 12, the exposed capping layer 150 is removed using a wet etch process and the like, and the second charge blocking layer 180 is formed on a resultant structure. The second charge blocking layer 180, for example, may include an oxide-nitride-oxide (ONO) thin film or a high-k metal oxide thin film. A first charge blocking layer 180 may be formed with a thickness that is insufficient for completely filling the trenches T1 to provide a space where a control gate may be formed in the trenches T1.

Before forming the second charge blocking layer 180, a first charge blocking layer 170 covering the upper surfaces of the substrate 100 is formed by performing the processes illustrated in FIGS. 8 to 11. The first charge blocking layer 170 substantially prevents charge movement between the substrate 100 and the control gate. The second charge blocking layer 180 substantially prevents charge movement between a control gate and the first and second charge storage layers 142 and 144

Referring to FIG. 13, a control gate conductive layer 190 is formed on the second charge blocking layer 180. The control gate conductive layer 190 may be formed of a polysilicon layer, a metal layer, or a layer obtained by sequentially stacking these layers.

Although not illustrated in FIG. 13, a process of simultaneously patterning the control gate conductive layer 190, the second charge blocking layer 180, and the first and second charge storage layers 142 and 144 may be further performed.

Through the above-mentioned processes, the device illustrated in FIG. 13 can be fabricated.

The non-volatile memory device and the method for fabricating the same in accordance with the present invention increases the degree of integration even in the same design rule.

While the present invention has been described with respect to the specific embodiments, it will be apparent to those skilled in the art that various changes and modifications may be made without departing from the spirit and scope of the invention as defined in the following claims.

What is claimed is:

1. A non-volatile memory device comprising:
a first storage layer making contact with a sidewall of an active region in an isolation trench and a second charge storage layer making contact with an opposite sidewall of the active region in the isolation trench;
first and second tunnel insulation layers interposed between the first charge storage layer and the active region and between the second charge storage layer and the active region;
a first charge blocking layer disposed over the first and second charge storage layers; and
a control gate disposed over the first charge blocking layer.

2. The non-volatile memory device of claim 1, wherein at least one of the first and second charge storage contains implanted impurities.

3. The non-volatile memory device of claim 2, wherein a type or concentration of impurity implanted into the first charge storage layer is different from that of impurity implanted into the second charge storage layer.

4. The non-volatile memory device of claim 1, wherein a thickness of the first tunnel insulation layer is different from that of the second tunnel insulation layer.

5. The non-volatile memory device of claim 1, wherein the first charge storage layer and the second charge storage layer include a floating gate layer.

6. The non-volatile memory device of claim 1, wherein the first charge storage layer and the second charge storage layer include a charge trap layer.

7. The non-volatile memory device of claim 1, further comprising:
a second charge blocking layer disposed over an upper surface of the active region.

8. The non-volatile memory device of claim 1, further comprising:
both sidewalls of the active region contain implanted impurities.

9. The non-volatile memory device of claim 8, wherein a type or concentration of impurity implanted into the sidewall of the active region is different from that of impurity implanted into the opposite sidewall of the active region.

10. A method for fabricating a non-volatile memory device, comprising:
etching a part of a substrate to form an isolation trench that defines an active region;
forming a first tunnel insulation layer over a sidewall of the active layer in the trench and a second tunnel insulation layer over an opposite sidewall of the active region in the trench;
forming first and second charge storage layers on the first and second tunnel insulation layers;
forming a first charge blocking layer over the first and second charge storage layers; and
forming a control gate conductive layer over the first charge blocking layer.

11. The method of claim 10, further comprising:
performing an impurity ion implantation process with respect to both sidewalls of the active region in the trench after the etching of the part of the substrate, wherein impurity ion concentration or energy in ion implantation for the sidewall of the active region is different from impurity ion concentration or energy in ion implantation for the opposite sidewall of the active region.

12. The method of claim 10, wherein a thickness of the first tunnel insulation layer is different from that of the second tunnel insulation layer.

13. The method of claim 10, further comprising:
implanting impurity ions into one of the first and second charge storage layers after the forming of the first and second charge storage layers.

14. The method of claim 10, further comprising:
implanting impurity ions into the first and second charge storage layers after the forming of the first and second charge storage layers,
wherein a type or concentration of the impurity ions implanted into the first charge storage layer is different from that of the impurity ions implanted into the second charge storage layer.

15. The method of claim 10, wherein the first and second charge storage layers comprises a floating gate layer.

16. The method of claim 10, wherein the first and second charge storage layers comprises a charge trap layer.

17. The method of claim 10, further comprising:
forming a second charge blocking layer over an upper surface of the active region before the forming of the first charge blocking layer.

18. The method of claim 17, wherein the forming of the second charge blocking layer comprises:
forming insulation patterns that expose the upper surface of the active region, and protruding upward further than the active region while covering the first and second charge storage layers;
forming the second charge blocking layer filled between the insulation patterns; and
removing the insulation patterns.

19. The method of claim 10, further comprising:
filling a part of the isolation trench with an insulation layer before the forming of the first and second tunnel insulation layers.

20. The non-volatile memory device of claim 1, further comprising:
an insulation layer filling a part of the isolation trench.
